(19) United States
(12) Patent Application Publication
(10) Pub. No.: US 2026/0018474 A1
(43) Pub. Date: Jan. 15, 2026

(54) SEMICONDUCTOR MODULE

(71) Applicant: FUJI ELECTRIC CO., LTD., Kawasaki-shi (JP)

(72) Inventor: Makoto ISOZAKI, Matsumoto-city (JP)

(73) Assignee: FUJI ELECTRIC CO., LTD., Kawasaki-shi (JP)

(21) Appl. No.: 19/221,139

(22) Filed: May 28, 2025

(30) Foreign Application Priority Data
Jul. 10, 2024 (JP) 2024-110728

(51) Int. Cl. H01L 23/10; H01L 23/00; H01L 23/057; H01L 23/08; H01L 23/40; H01L 25/065

(52) U.S. Cl. CPC H01L 23/10; H01L 23/057; H01L 23/4006; H01L 23/562; H01L 23/08; H01L 25/0655

(57) ABSTRACT

A semiconductor module includes a plate-shaped base made of metal, and a frame-shaped housing made of a resin composition, the housing having an adhering portion adhering to an outer peripheral portion of the base, wherein in plan view, an outer periphery of the housing includes first sides facing each other and second sides facing each other, a portion of the housing corresponding to each of the second sides is provided with at least one hole for screwing a heat dissipating member, the adhering portion includes a plate-shaped first adhering portion extending along each of the first sides, in plan view, the first adhering portion overlaps an outer periphery of the base, and inequality T₁<0.42×L₁² is satisfied, when T₁ is T₁ meters that denote a thickness of the first adhering portion, and L₁ is L₁ meters that denote a length of the first adhering portion.

### CROSS REFERENCE TO RELATED APPLICATION

This application is based on, and claims priority from, Japanese Patent Application No. 2024-110728, filed on Jul. 10, 2024, the entire contents of which are incorporated herein by reference.

### BACKGROUND

### Technical Field

This disclosure relates to semiconductor modules.

### Related Art

In a semiconductor module such as a power semiconductor module, a housing for accommodating semiconductor chips, etc., is bonded to a base for dissipating heat, as disclosed in Japanese Patent Application Laid-Open Publication No. 2021-190685, Japanese Patent Application Laid-Open Publication No. 2021-57447, and Japanese Patent Application Laid-Open Publication No. 2015-220238, for example. In a case in which a base has a shape of a plate as described in Japanese Patent Application Laid-Open Publication No. 2021-190685, a heat dissipating member such as a heatsink is screwed to a housing so as to be in close contact with a surface of the base facing away from the housing.

In a conventional state, the surface of the base facing away from the housing may be a convex curved surface, either by design or by chance. In this case, by screwing the heat dissipating member to the housing, the base is deformed to be in close contact with the heat dissipating member; thus, stress is applied to the housing. There is therefore concern that the housing may be damaged due to this stress being excessive.

### SUMMARY

In view of the circumstances described above, an object of one aspect according to this disclosure is to reduce damage to a housing due to screwing of the housing.

To solve the above problem, a semiconductor module according to an aspect of this disclosure includes a plate-shaped base made of metal, and a frame-shaped housing made of a resin composition, the housing having an adhering portion adhering to an outer peripheral portion of the base, wherein in plan view, an outer periphery of the housing includes a pair of first sides facing each other and a pair of second sides facing each other, wherein a portion of the housing corresponding to each of the second sides is provided with at least one hole for screwing a heat dissipating member, wherein the adhering portion includes a plate-shaped first adhering portion extending along each of the first sides, wherein in plan view, the first adhering portion overlaps an outer periphery of the base, and wherein inequality T₁<0.42×L₁² is satisfied, when T₁ is T₁ meters that denote a thickness of the first adhering portion, and L₁ is L₁ meters that denote a length of the first adhering portion.

### BRIEF DESCRIPTION OF THE DRAWINGS

FIG. 1 is a plan view of a semiconductor module according to a First Embodiment.

FIG. 2 is a cross section taken along line A-A shown in FIG. 1.

FIG. 3 is a diagram showing an example of a curved shape of a base.

FIG. 4 is a diagram explaining the attachment of a heat dissipating member to a semiconductor module.

FIG. 5 is a plan view of a housing of the semiconductor module according to the First Embodiment.

FIG. 6 is a plan view of a base of the semiconductor module according to the First Embodiment.

FIG. 7 is an explanatory diagram showing the thickness of, and the width of, a first adhering portion of the semiconductor module according to the First Embodiment.

FIG. 8 is an explanatory diagram showing the thickness of, and the width of, a second adhering portion of the semiconductor module according to the First Embodiment.

FIG. 9 is an explanatory diagram showing the thickness of, and the length of, the first adhering portion of the semiconductor module according to the First Embodiment.

FIG. 10 is an explanatory diagram showing an operation of the first adhering portion.

FIG. 11 is an explanatory diagram showing a semiconductor module according to a Second Embodiment.

### DESCRIPTION OF EMBODIMENTS

Embodiments according to this disclosure will be described with reference to the drawings. In the drawings, dimensions and scales of elements may differ from those of actual products, and some elements may be shown schematically to facilitate understanding. The scope of this disclosure is not limited to these embodiments described below unless the following explanation includes a description that specifically limits the scope of this disclosure.

### 1. First Embodiment

### 1-1. Overall Configuration of Semiconductor Module

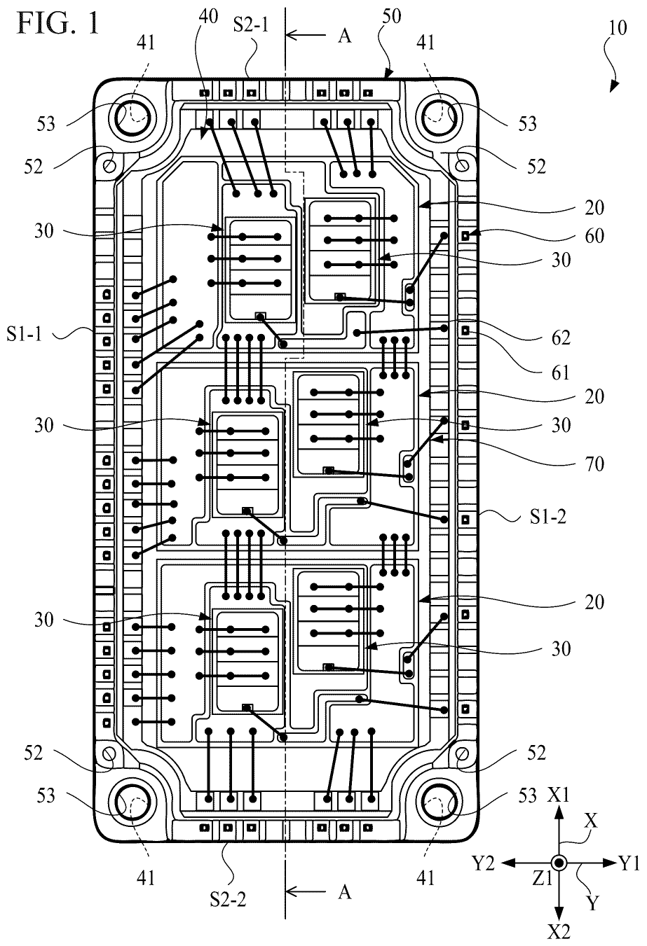

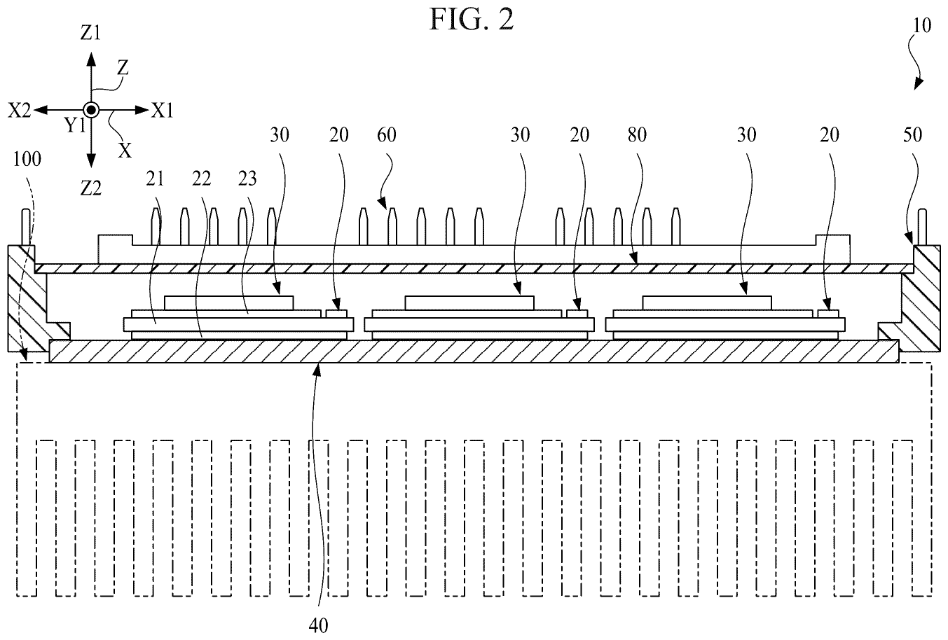

FIG. 1 is a plan view of a semiconductor module 10 according to a First Embodiment. FIG. 2 is a cross section taken along line A-A shown in FIG. 1. The semiconductor module 10 is a power module such as an insulated gate bipolar transistor (IGBT) module. The semiconductor module 10 is used, for example, to execute power control of a device such as an inverter or a rectifier. The inverter or the rectifier may be provided to an apparatus such as a rail vehicle, an automobile, or a household electrical appliance.

As shown in FIG. 1 and FIG. 2, the semiconductor module 10 includes a plurality of insulating substrates 20, a plurality of semiconductor chips 30, a base 40, a housing 50, a plurality of external terminals 60, a plurality of wires 70, and a lid 80. It should be noted that in FIG. 1, the lid 80 is omitted. In FIG. 2, the plurality of wires 70 is omitted.

First, each element of the semiconductor module 10 will be described with reference to FIG. 1 and FIG. 2. It should be noted that, for convenience, in the following description, an X-axis, a Y-axis, and a Z-axis are defined that are perpendicular to one another. The Z-axis is an axis parallel to a direction of thickness of the semiconductor module 10. In the following description, a direction along the X-axis is referred to as a direction X1, and a direction opposite to the direction X1 is referred to as a direction X2. A direction along the Y-axis is referred to as a direction Y1, and a direction opposite to the direction Y1 is referred to as a direction Y2. A direction along the Z-axis is referred to as a direction Z1, and a direction opposite to the direction Z1 is referred to as a direction Z2. The relationship between each of these directions and the vertical direction is not particularly limited, and the relationship may be freely selected. In the following description, a view in a direction along the Z-axis may be referred to as a “plan view.”

Each of the plurality of insulating substrates 20 is a substrate such as a direct copper bonding (DCB) substrate or a direct bonded aluminum (DBA) substrate. An insulating substrate 20, which is any one of the plurality of insulating substrates 20, has two surfaces. One surface of the two surfaces of the insulating substrate 20 is provided with two or more semiconductor chips 30 among the plurality of semiconductor chips 30, and the other surface of the two surfaces of the insulating substrate 20 is joined to the base 40. In an example shown in FIG. 1, a direction of thickness of the insulating substrate 20 is the direction along the Z-axis. A surface of the insulating substrate 20 facing in the direction Z1 is provided with the two or more semiconductor chips 30. A surface of the insulating substrate 20 facing in the direction Z2 is joined to the base 40.

Specifically, as shown in FIG. 2, the insulating substrate 20 includes an insulating board 21, a conductor board 22, and conductor patterns 23.

The insulating board 21 is an insulating plate-shaped member that is disposed such that a direction of thickness of the insulating board 21 is the direction along the Z-axis. The insulating board 21 is made of, for example, a ceramic material such as an aluminum nitride material, an aluminum oxide material, or a silicon nitride material.

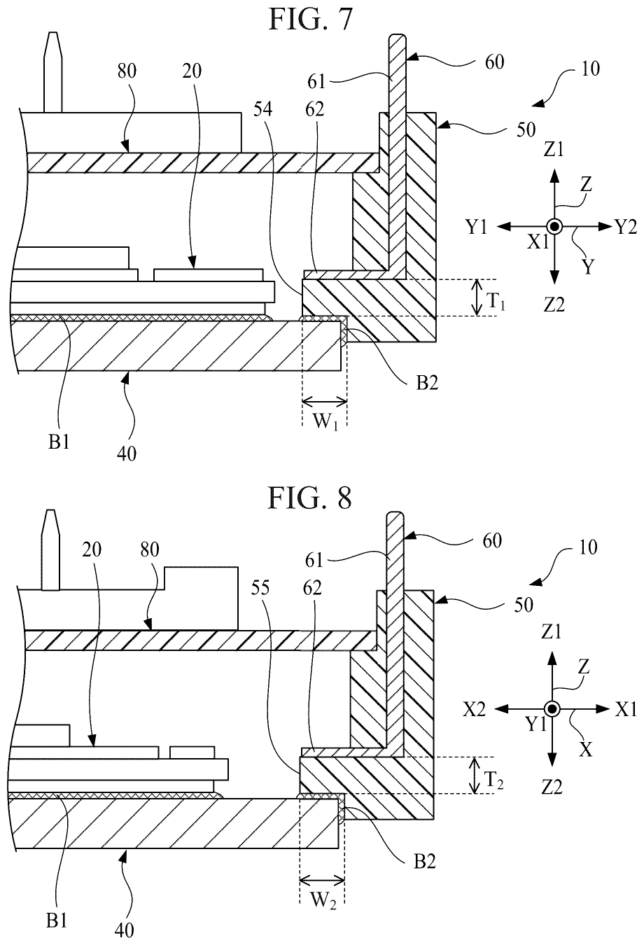

The conductor board 22 is a plate-shaped conductor that is disposed on substantially the entire area of the surface of the insulating board 21 facing in the direction Z2. The conductor board 22 is made of, for example, metal such as copper or aluminum. The conductor board 22 is joined by a joining material B1, which is a solder material, etc., shown in FIG. 7 and FIG. 8 described below, to the base 40.

The conductor patterns 23 are disposed on a surface of the insulating board 21. The conductor patterns 23 include conductors joined to the two or more semiconductor chips 30. In this embodiment, the conductor patterns 23 are disposed on the surface of the insulating board 21 facing in the direction Z1. The conductor patterns 23 include separate conductors. The conductor patterns 23 are made of, for example, metal such as copper or aluminum, as is the conductor board 22. The conductor patterns 23 are joined by joining materials such as solder materials (not shown) to the two or more semiconductor chips 30.

As described above, the insulating substrate 20 is disposed on a surface of the base 40. The insulating substrate 20 is provided with at least one semiconductor chip 30. It should be noted that the number of semiconductor chips 30 provided to the insulating substrate 20 is freely selected. In addition, the number of insulating substrates 20 included in the semiconductor module 10 is not limited to the example shown in FIG. 1, and it may be two or fewer, or may be four or more.

At least one of the two or more semiconductor chips 30 provided to the insulating substrate 20 is a power semiconductor chip such as an IGBT. In this embodiment, the insulating substrate 20 is provided with the two or more semiconductor chips 30 that include not only a switching element such as an IGBT, but also a control chip for controlling operation of the power semiconductor chip. A back surface of the switching element is provided with an input electrode, which is either a drain electrode or a collector electrode. On the other hand, a front surface of the switching element is provided with an output electrode, which is either a source electrode or an emitter electrode, and a control electrode, which is a gate electrode. Alternatively, the insulating substrate 20 may be further provided with an element such as a freewheeling diode (FWD) that allows a load current to return. It should be noted that the control chip, which is a semiconductor chip 30, may be provided, or may be omitted, as appropriate. In addition, the arrangement of the two or more semiconductor chips 30 on the insulating substrate 20 is not limited to the example shown in FIG. 1, and it may be freely selected.

The base 40 is a plate-shaped member made of metal. For example, the base 40 is made of metal such as copper, an alloy of copper, aluminum, or an alloy of aluminum. The base 40 has high thermal conductivity. The base 40 dissipates heat conducted from the plurality of semiconductor chips 30. The base 40 further has high electrical conductivity. The base 40 is electrically connected to a reference potential line such as a ground potential line.

In the example shown in FIG. 1, a direction of thickness of the base 40 is the direction along the Z-axis. The base 40 has a surface facing in the direction Z1 and a surface facing in the direction Z2. The surface of the base 40 facing in the direction Z1 is provided with the plurality of insulating substrates 20. The surface of the base 40 facing in the direction Z2 is joined to a heat dissipating member 100 such as heat dissipating fins as shown in long-dash, double short-dash line shown in FIG. 2. As viewed in the direction along the Z-axis, the base 40 is shaped to have a pair of long sides extending in the direction along the X-axis and a pair of short sides extending in the direction along the Y-axis. The base 40 is provided with holes 41 in a vicinity of each of the short sides. Each of the holes 41 is a through hole for screwing the heat dissipating member 100 to the base 40. In plan view, the shape of the base 40 is not limited to the example shown in FIG. 1 and may be freely selected. The base 40 may be replaced with two or more bases 40. It should be noted that the holes 41 may be provided, or may be omitted, as appropriate.

The housing 50 is a frame-shaped member for accommodating the plurality of insulating substrates 20 and the plurality of semiconductor chips 30. The housing 50 has a shape of a frame surrounding the plurality of insulating substrates 20 and the plurality of semiconductor chips 30. The housing 50 is substantially an insulator. For example, the housing 50 may be made of a resin composition including a resin material such as a polyphenylene sulfide (PPS) material or a polybutylene terephthalate (PBT) material. It should be noted that the resin composition may further include an inorganic filler made of, for example, an alumina material or a silica material so as to improve mechanical strength of the housing 50, or so as to reduce a thermal expansion coefficient of the housing 50.

In the example shown in FIG. 1, a direction of thickness of the housing 50 is the direction along the Z-axis. A surface of the housing 50 facing in the direction Z2 is bonded to the base 40. Details of the adhesion between the base 40 and the housing 50 will be described with reference to FIG. 7 and FIG. 8.

The plurality of external terminals 60 is arranged along a circumferential direction of the housing 50. The plurality of external terminals 60 passes through the housing 50.

In the example shown in FIG. 1, the direction of thickness of the housing 50 is the direction along the Z-axis. As viewed in the direction along the Z-axis, an outer periphery of the housing 50 includes a pair of first sides S1-1 and S1-2 extending in the direction along the X-axis, and a pair of second sides S2-1 and S2-2 extending in the direction along the Y-axis; thus, an outer shape of the housing 50 is substantially rectangular. In the following, each of the first sides S1-1 and S1-2 may be referred to as a first side S1 without distinguishing therebetween, and each of the second sides S2-1 and S2-2 may be referred to as a second side S2 without distinguishing therebetween. In this embodiment, the length of each of the first sides S1 is greater than the length of each of the second sides S2.

As described above, in plan view, the outer periphery of the housing 50 includes the pair of first sides S1 facing each other and the pair of second sides S2 facing each other. A portion of the housing 50 corresponding to each of the second sides S2 is provided with two holes 52 and two holes 53. Thus, the housing 50 is provided with four holes 52 and four holes 53. The four holes 52 are holes for screwing a board (not shown), which is to be provided with the semiconductor module 10, to the housing 50. The four holes 53 are holes for screwing the heat dissipating member 100. The four holes 53 are provided at locations corresponding to the four corners of the housing 50. In other words, the four holes 53 are provided at locations close to the four corners of the housing 50. Thus, it is possible to firmly fix the housing 50 to the heat dissipating member 100 by screwing the housing 50 to the heat dissipating member 100. It should be noted that the shape of the housing 50 is not limited to the example shown in FIG. 1 and may be freely selected. In addition, the holes 52 may be provided, or may be omitted, as appropriate. In addition, the number of holes 53 is not limited to the example shown in FIG. 1 and the arrangement of the holes 53 is not limited to the example shown in FIG. 1. For example, two holes 53 may be provided at locations corresponding to the middle of each of the second sides S2 as in a Second Embodiment. As described above, the length of each of the first sides S1 is greater than the length of each of the second sides S2. Thus, by virtue of the holes 53 being provided at locations corresponding to the second sides S2, compared to a configuration in which the length of each of the first sides S1 is less than the length of each of the second sides S2, it is possible to firmly fix the housing 50 to the heat dissipating member 100 by screwing the housing 50 to the heat dissipating member 100 if the number of holes 53 is small.

Each of the plurality of external terminals 60 is a terminal for electrically connecting the plurality of semiconductor chips 30 to the substrate (not shown) to be provided with the semiconductor module 10. Each of the plurality of external terminals 60 has a portion, which is disposed in the housing 50, and a portion protruding from the housing 50. The plurality of external terminals 60 is electrically connected to the plurality of semiconductor chips 30. Each of the plurality of external terminals 60 is made of metal such as copper, an alloy of copper, aluminum, an alloy of aluminum, or an alloy of iron, for example. Each of the plurality of external terminals 60 may have a plated surface such as a surface plated with Sn, for example.

The plurality of external terminals 60 included in the semiconductor module 10 includes a first plurality of external terminals 60 and a second plurality of external terminals 60 other than the first plurality of external terminals 60. The first plurality of external terminals 60 are main terminals through each of which a main current flows. The second plurality of external terminals 60 are control terminals for controlling operation of the plurality of semiconductor chips 30.

The plurality of wires 70 is a group of conductive wires constituted of bonding wires for electrically connecting the plurality of external terminals 60 and the plurality of semiconductor chips 30 to each other. In the example shown in FIG. 1, the plurality of wires 70 includes a plurality of wires 70 for electrically connecting the plurality of external terminals 60 and the conductor patterns 23 to each other, a plurality of wires 70, each electrically connecting two conductor patterns 23 among the conductor patterns 23 to each other, and a plurality of wires 70 for electrically connecting the conductor patterns 23 and the semiconductor chips 30.

The lid 80 is a plate-shaped member joined to a surface of the housing 50 facing in the direction Z1. The lid 80 is made of a resin material such as a PPS material or a PBT material, as is the housing 50, for example. The lid 80 is bonded by an adhesive, etc., to the housing 50 such that a gap between the lid 80 and the housing 50 is sealed.

The base 40, the housing 50, and the lid 80 surround a space. The space surrounded by the base 40, the housing 50, and the lid 80 is filled with a potting material that encapsulates the plurality of semiconductor chips 30. The potting material is made of, for example, an epoxy resin or a silicone resin such as a silicone gel material.

### 1-2. Base and Housing

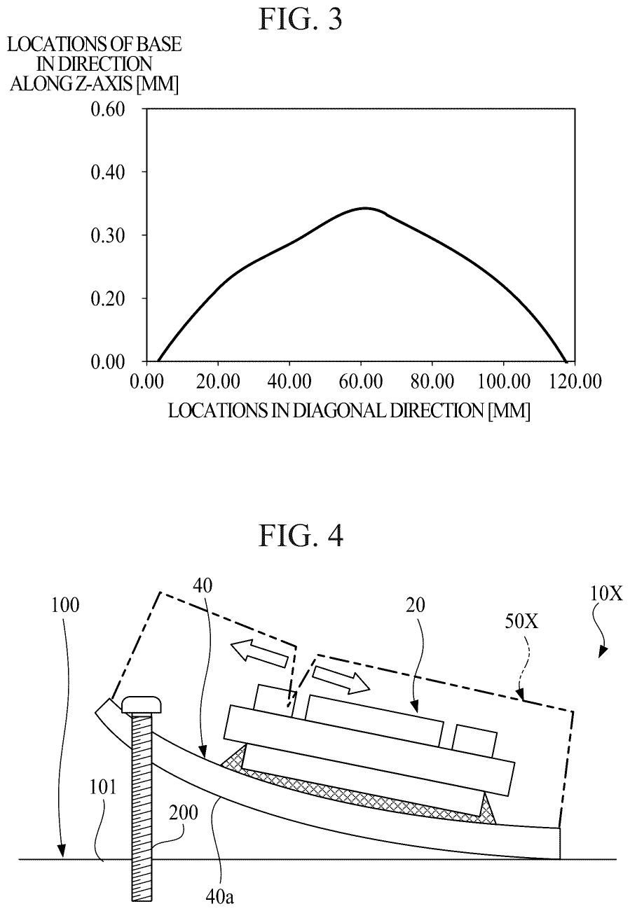

FIG. 3 is a diagram showing an example of a curved shape of the base 40. FIG. 3 shows a relationship between locations of portions of the base 40 in a direction along a diagonal line and locations of the portions of the base 40 in the direction along the Z-axis. The direction along the diagonal line denotes a direction that is perpendicular to the Z axis and that is along a straight line passing through two opposite holes 53 among the four holes 53 of the housing 50. In FIG. 3, a horizontal axis represents, in the direction along the diagonal line, locations of portions of the surface of the base 40 facing in the direction Z2, the locations being specified based on a location of one hole 53 of the two opposite holes 53. A vertical axis represents, in the direction along the Z-axis, locations of the portions of the surface of the base 40 facing in the direction Z2, the locations being specified based on locations of both ends of the surface of the base 40 facing in the direction Z2, both the ends of the surface of the base 40 facing in the direction Z2 being in the direction along the diagonal line.

In a state in which no fastening force caused by screwing the heat dissipating member 100 to the housing 50 is applied, the base 40 is convexly bent away from the housing 50, as shown in FIG. 3. Thus, the surface of the base 40 facing in the direction Z2 is convexly bent toward a mounting surface of the heat dissipating member 100. The base 40 is bent as described above. Thus, when thermal grease is interposed between the base 40 and the heat dissipating member 100, it is possible to appropriately spread the thermal grease by the heat dissipating member 100 being screwed to the housing 50.

Such a shape of the base 40 may be a shape produced on purpose, for example. Alternatively, the shape of the base 40 may be an inevitable shape due to a molding method such as press molding of the base 40. The shape of the base 40 may be a shape due to a stress difference caused by joining the insulating substrate 20 and the base 40 to each other. The shape of the base 40 may be a shape due to a combination of two or more shapes of the shapes described above.

In this embodiment, as described above, the insulating substrate 20 is joined to the base 40. Thus, due to stress caused by joining the insulating substrate 20 to the base 40, the base 40 may warp. In this case, an advantage can be obtained in that by deformation of an adhering portion 5 described below, it is possible to reduce stress, which occurs in the housing 50 when the housing 50 is screwed to the heat dissipating member 100.

FIG. 4 is a diagram explaining the attachment of the heat dissipating member 100 to a semiconductor module 10X. FIG. 4 schematically shows a part of the semiconductor module 10X. The semiconductor module 10X has substantially the same configuration as the semiconductor module 10, except that a housing 50X is included in place of the housing 50. The housing 50X has substantially the same configuration as the housing 50, except that in plan view, a portion of the housing 50X overlapping the base 40 differs in configuration from that of the housing 50. It should be noted that in FIG. 4, for convenience, a part of the housing 50X is shown in long-dash, double short-dash line, and deformation of the housing 50X is exaggerated.

As shown in FIG. 4, at the beginning of attaching the heat dissipating member 100 to the housing 50X with screws 200, a mounting surface 101 of the heat dissipating member 100 is planar, whereas the surface of the base 40 facing in the direction Z2 is convexly bent toward the mounting surface 101 as described above. Thus, with the screws 200 being tightened, the base 40 is deformed so as to be in close contact with the heat dissipating member 100; as a result, stress is applied to the housing 50X as described by arrows shown in FIG. 4. In this case, with an increase in the thickness of the portion of the housing 50X overlapping the base 40, stress occurring in the portion of the housing 50X increases. As a result, the housing 50X is likely to be damaged and there is a risk of insulation failure in the housing 50X.

Thus, in the semiconductor module 10, at least a section of a portion of the housing 50 overlapping the base 40 has a shape of a plate that is thinner than the other section of the portion of the housing 50 overlapping the base 40. In this way, it is possible to reduce damage to the housing 50. In the following, the housing 50 will be described in detail.

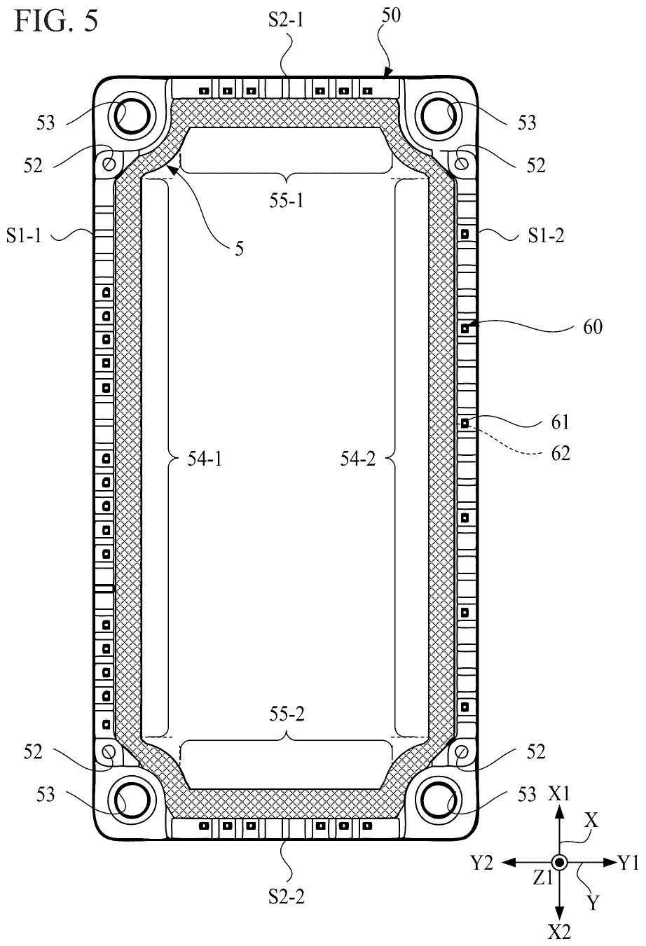

FIG. 5 is a plan view of the housing 50 of the semiconductor module 10 according to the First Embodiment. As shown in FIG. 5, the housing 50 has the adhering portion 5. The adhering portion 5 is a frame-shaped portion of the housing 50 for adhering to an outer peripheral portion of the base 40. A direction of thickness of the adhering portion 5 is the direction along the Z-axis. A surface of the adhering portion 5 facing in the direction Z2 is bonded to the outer peripheral portion of the base 40. It should be noted that in FIG. 5, for ease of visibility, the adhering portion 5 is shaded and legs 62 of the external terminals 60, which are disposed on a surface of the adhering portion 5 facing in the direction Z1 as described below, are omitted.

The adhering portion 5 includes first adhering portions 54-1 and 54-2 and second adhering portions 55-1 and 55-2. In the following, each of the first adhering portions 54-1 and 54-2 may be referred to as a first adhering portion 54 without distinguishing therebetween, and each of the second adhering portions 55-1 and 55-2 may similarly be referred to as a second adhering portion 55.

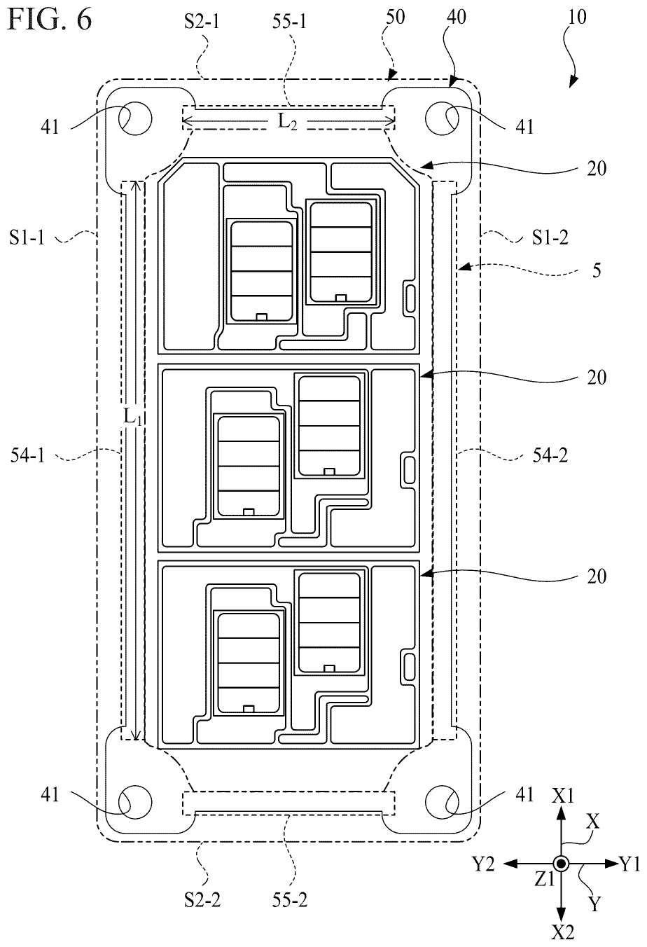

The first adhering portion 54-1 is a plate-shaped portion of the housing 50. As shown in FIG. 7, the first adhering portion 54-1 protrudes toward the inside of the housing 50. As shown in FIG. 6, the first adhering portion 54-1 extends along the first side S1-1 and has a length L₁. The first adhering portion 54-2 is a plate-shaped portion of the housing 50. The first adhering portion 54-2 protrudes toward the inside of the housing 50. The first adhering portion 54-2 extends along the first side S1-2 and has a length L₁.

The second adhering portion 55-1 is a plate-shaped portion of the housing 50. As shown in FIG. 8, the second adhering portion 55-1 protrudes toward the inside of the housing 50. As shown in FIG. 6, the second adhering portion 55-1 extends along the second side S2-1 and has a length L₂. The second adhering portion 55-2 is a plate-shaped portion of the housing 50. The second adhering portion 55-2 protrudes toward the inside of the housing 50. The second adhering portion 55-2 extends along the second side S2-2 and has a length L₂.

FIG. 6 is a plan view of the base 40 of the semiconductor module 10 according to the First Embodiment. In FIG. 6, for comparison with the base 40, the housing 50 is shown in long-dash, double short-dash line, and the first adhering portion 54 and the second adhering portion 55 are shown in dashed line.

As shown in FIG. 6, in plan view, each of the entire first adhering portions 54-1 and 54-2 having the length L₁ overlaps an outer periphery of the base 40. As described above, in plan view, each of the first adhering portions 54-1 and 54-2 overlaps the base 40, and there is no portion of the base 40 in a region outside each of the first adhering portions 54-1 and 54-2. Thus, by deformation of the first adhering portion 54, it is possible to reduce stress that occurs in the housing 50 when the housing 50 is screwed to the heat dissipating member 100.

On the other hand, in plan view, each of the entire second adhering portions 55-1 and 55-2 having the length L₂ overlaps the outer periphery of the base 40. As described above, in plan view, each of the second adhering portions 55-1 and 55-2 overlaps the base 40, and there is no portion of the base 40 in a region outside each of the second adhering portions 55-1 and 55-2. Thus, by deformation of the second adhering portion 55, it is possible to reduce stress that occurs in the housing 50 when the housing 50 is screwed to the heat dissipating member 100.

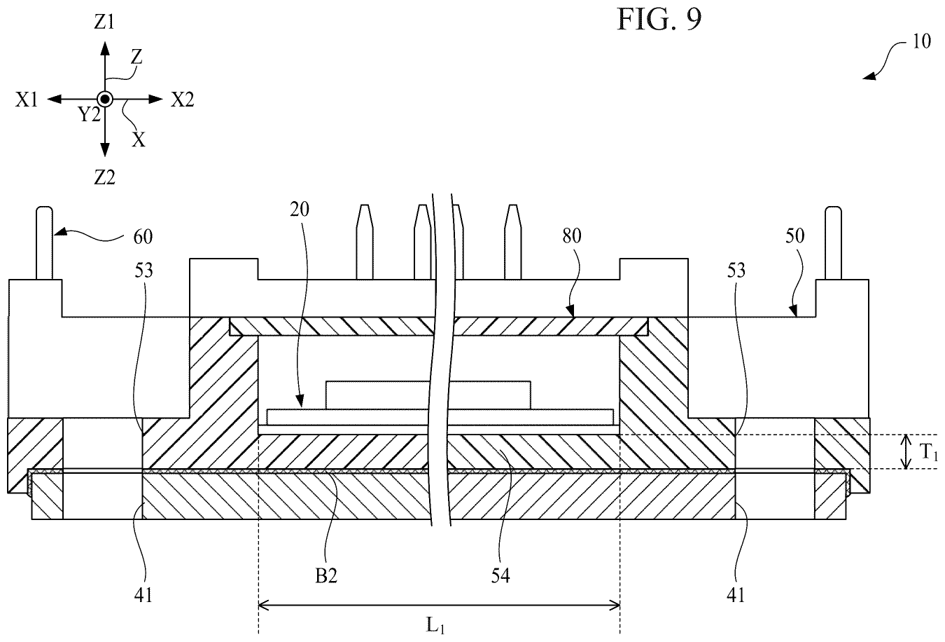

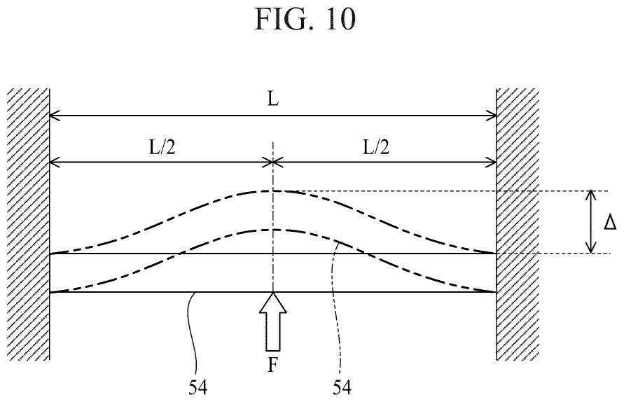

FIG. 7 is an explanatory diagram showing a thickness T₁ and a width W₁ of the first adhering portion 54 of the semiconductor module 10 according to the First Embodiment. FIG. 8 is an explanatory diagram showing a thickness T₂ and a width W₂ of the second adhering portion 55 of the semiconductor module 10 according to the First Embodiment. FIG. 9 is an explanatory diagram showing the thickness T₁ and the length L₁ of the first adhering portion 54 of the semiconductor module 10 according to the First Embodiment. It should be noted that FIG. 7 shows a cross section of the semiconductor module 10, the cross section being perpendicular to the X-axis and including a cross section of the first adhering portion 54. FIG. 8 shows a cross section of the semiconductor module 10, the cross section being perpendicular to the Y-axis and including a cross section of the second adhering portion 55. FIG. 9 shows a cross section of the semiconductor module 10, the cross section being perpendicular to the Y-axis and including a cross section of the first adhering portion 54.

As shown in FIG. 7, the first adhering portion 54 has a shape of a plate. A direction of thickness of the first adhering portion 54 is the direction along the Z-axis. A surface of the first adhering portion 54 facing in the direction Z2 is bonded by an adhesive B2 to the outer peripheral portion of the base 40.

As shown in FIG. 8, the second adhering portion 55 has a shape of a plate. A direction of thickness of the second adhering portion 55 is the direction along the Z-axis. A surface of the second adhering portion 55 facing in the direction Z2 is bonded by the adhesive B2 to the outer peripheral portion of the base 40.

The adhesive B2 is, for example, an epoxy adhesive or a silicone adhesive.

An external terminal 60, which is any one of the external terminals 60, has a portion that is disposed either on a surface of the first adhering portion 54 facing in the direction Z1 or on a surface of the second adhering portion 55 facing in the direction Z1.

Specifically, the external terminal 60 is made of a metallic plate with an L-shape. The external terminal 60 includes a pin 61 and a leg 62.

The pin 61 is a portion of the external terminal 60. The pin 61 has a shape of a bar extending in the direction along the Z-axis. The pin 61 has an end in the direction Z1 and an end in the direction Z2. The end of the pin 61 in the direction Z1 protrudes from an outer wall surface of the housing 50. On the other hand, the end of the pin 61 in the direction Z2 is connected to the leg 62. It should be noted that the shape of the pin 61 is not limited to the example shown in FIG. 1. For example, the shape of the pin 61 may be such that a tip portion of the pin 61 branches into two parts.

The leg 62 is a portion of the external terminal 60. The leg 62 has a shape of a plate connected to an end of a wire 70 among the plurality of wires 70. The leg 62 extends from the end of the pin 61, which is in the direction Z2, toward the inside of the housing 50. The leg 62 is disposed either on the surface of the first adhering portion 54 facing in the direction Z1 or on the surface of the second adhering portion 55 facing in the direction Z1. The leg 62 includes a pad that is exposed in a space in an inward direction from the housing 50. Although not shown in FIG. 7 and FIG. 8, the pad is joined to one end of the wire 70. The other end of the wire 70 is connected to a conductor pattern 23 among the conductor patterns 23. It should be noted that the leg 62 may be disposed on a surface of a portion of the housing 50, the portion of the housing 50 being different from each of the first adhering portion 54 and the second adhering portion 55.

As shown in FIG. 9, the first adhering portion 54 with the length L₁ is bonded by the adhesive B2 to the base 40. Although not shown, similarly, the second adhering portion 55 with the length L₂ is bonded by the adhesive B2 to the base 40. It should be noted that, although not shown, an entire surface of the frame-shaped adhering portion 5 is bonded by the adhesive B2 to the base 40.

Inequality T₁<0.42×L₁² is satisfied, when T₁ is T₁ meters that denote a thickness of the first adhering portion 54 (or a length of the first adhering portion 54 along the Z-axis), and L₁ is L₁ meters that denote a length of the first adhering portion 54 (or a length of the first adhering portion 54 along the X-axis). In this way, by deformation of the first adhering portion 54, it is possible to appropriately reduce stress that occurs in a portion of the housing 50 that is along the first side S1. Similarly, inequality T₂<0.42×L₂² is satisfied, when T₂ is T₂ meters that denote a thickness of the second adhering portion 55 (or a length of the second adhering portion 55 along the Z-axis), and L₂ is L₂ meters that denote a length of the second adhering portion 55 (or a length of the second adhering portion 55 along the Y-axis). In this way, by deformation of the second adhering portion 55, it is possible to reduce stress that occurs in a portion of the housing 50 that is along the second side S2.

In the example shown in FIG. 9, the thickness T₁ of the first adhering portion 54 is constant in a direction of length of the first adhering portion 54. The thickness T₂ of the second adhering portion 55 is constant in a direction of length of the second adhering portion 55. It should be noted that the thickness of the first adhering portion 54 is not required to be constant in the direction of length of the first adhering portion 54. In other words, at least one surface of the first adhering portion 54 may be provided with irregularities. In this case, the thickness T₁ is an average thickness of the first adhering portion 54. Similarly, the thickness of the second adhering portion 55 is not required to be constant in the direction of length of the second adhering portion 55. In other words, at least one surface of the second adhering portion 55 may be provided with irregularities. In this case, the thickness T₂ is an average thickness of the second adhering portion 55.

FIG. 10 is an explanatory diagram showing an operation of the first adhering portion 54. In FIG. 10, the first adhering portion 54 is shown as a model of a beam with both ends fixed. It should be noted that in the following, an operation of the first adhering portion 54 is given as an example, and an operation of the second adhering portion 55 is substantially the same as that of the first adhering portion 54.

Both ends of the first adhering portion 54 in a longitudinal direction of the first adhering portion 54 are fixed to inside surfaces of the frame-shaped housing 50. Thus, as shown in FIG. 10, the first adhering portion 54 can be represented by a beam with both ends fixed. As described above, the surface of the base 40 facing in the direction Z2 is convexly bent. Thus, while the heat dissipating member 100 is being screwed to the housing 50 by use of the holes 53, a shape of the surface of the base 40 facing in the direction Z2 is gradually changed into a plane; as a result, a load is applied to the middle of the first adhering portion 54 in the longitudinal direction. Thus, this model of a beam with both ends fixed can be understood as a model of a central concentrated load. In this case, a deflection 8 of the first adhering portion 54 is represented based on the following equation (1):

$$δ = {{FL}_{1}}^{3} / 192 EI \qquad ( 1 )$$

In the equation (1), F is a load [N], L₁ is a length [m] of the first adhering portion 54, E is the Young's modulus [Pa] of the first adhering portion 54, and I is second moment of area [m⁴] of the first adhering portion 54.

In addition, assuming that a cross section of the first adhering portion 54 is rectangular, a second moment of area I[m⁴] of the first adhering portion 54, a section modulus Z, and a maximum stress σₘₐₓ are represented based on the following equations (2):

$$I = ( {W}_{1} \times {{T}_{1}}^{3} ) / 12 \qquad ( 2 )$$

$$Z = ( {W}_{1} \times {{T}_{1}}^{2} ) / 6$$

$${σ}_{max} = FL / 8 Z$$

In the equations (2), W₁ is a width of the first adhering portion 54, and T₁ is a thickness of the first adhering portion 54.

From the equation (1) and the equations (2), the thickness T₁ is simply represented based on the following equation (3):

$${T}_{1} = ( {σ}_{max} \times {{L}_{1}}^{2} ) / ( 12 \times E \times δ ) \qquad ( 3 )$$

In view of a size of a typical power module, the equation L₁=100 mm is assumed to be satisfied. In view of a total of a warp in the base 40, a warp in the mounting surface 101 of the heat dissipating member 100, and a margin, the equation δ=1000 μm is assumed to be satisfied. In view of flexural strength of PPS of 150 MPa and a margin, the equation σₘₐₓ=100 [MPa] is assumed to be satisfied. In view of the Young's modulus of PPS, the equation E=20 GPa is assumed to be satisfied. These values are substituted for the equation (3); as a result, the thickness T₁ is approximately 4.17 [mm].

In addition, when a material with lower flexural strength is used, a state may occur in which warps in the base 40, etc., are greater than warps described above. In view of this state, it is desirable to reduce the thickness T₁ compared to the value described above. Furthermore, L₁ varies depending on the size of the semiconductor module 10. Thus, it is desirable to satisfy the relationship of the following inequality (4):

$${T}_{1} < 0.42 \times {{L}_{1}}^{2} \qquad ( 4 )$$

Therefore, when inequality T₁<0.42×L₁² is satisfied, it is possible to reduce damage to the first adhering portion 54. It should be noted that T₁ and L₁ can be replaced with T₂ and L₂, respectively. In this case, when inequality T₂<0.42×L₂² is satisfied, it is possible to reduce damage to the second adhering portion 55.

It is desirable to satisfy inequality W₁>T₁, when W₁ is a width of the first adhering portion 54 (or a length of the first adhering portion 54 along the Y-axis). In this way, by deformation of the first adhering portion 54, it is possible to appropriately reduce stress that occurs in a portion of the housing 50 that is along the first side S1. On the other hand, in a case in which relationship W₁≤T₁ is satisfied, it is difficult to sufficiently ensure a bonding area between the base 40 and the housing 50 depending on the thickness T₁, etc., and it is difficult to sufficiently ensure mechanical strength required for the first adhering portion 54 depending on a material of the first adhering portion 54, etc.

In the example shown in FIG. 7, the width W₁ of the first adhering portion 54 is constant in the direction of length of the first adhering portion 54. It should be noted that the width of the first adhering portion 54 is not required to be constant in the direction of length of the first adhering portion 54. In this case, the width W₁ is an average width of the first adhering portion 54.

The length L₁ of the first adhering portion 54 is preferably 50% or more of the length of the first side S1, and is more preferably 60% or more of the length of the first side S1. In this way, by deformation of the first adhering portion 54, it is possible to appropriately reduce stress that occurs in a portion of the housing 50 that is along the first side S1.

It is desirable to satisfy inequality W₂>T₂, when W₂ is a width of the second adhering portion 55 (or a length of the second adhering portion 55 along the X-axis). In this way, by deformation of the second adhering portion 55, it is possible to appropriately reduce stress that occurs in a portion of the housing 50 that is along the second side S2. On the other hand, in a case in which relationship W₂≤T₂ is satisfied, it is difficult to sufficiently ensure a bonding area between the base 40 and the housing 50 depending on the thickness T₂, etc., and it is difficult to sufficiently ensure mechanical strength required for the second adhering portion 55 depending on the material of the second adhering portion 55, etc.

In the example shown in FIG. 8, the width W₂ of the second adhering portion 55 is constant in the direction of length of the second adhering portion 55. It should be noted that the width of the second adhering portion 55 is not required to be constant in the direction of length of the second adhering portion 55. In this case, the width W₂ is an average width of the second adhering portion 55.

The length L₂ of the second adhering portion 55 is preferably 50% or more of the length of the second side S2, and is more preferably 60% or more of the length of the second side S2. In this way, by deformation of the second adhering portion 55, it is possible to appropriately reduce stress that occurs in a portion of the housing 50 that is along the second side S2.

### 2. Second Embodiment

In the following, a Second Embodiment according to this disclosure will be described. In the embodiment described below, for elements having effects and functions substantially the same as those of the First Embodiment, reference signs used in the descriptions of the First Embodiment are used, and detailed explanations of such elements are omitted as appropriate.

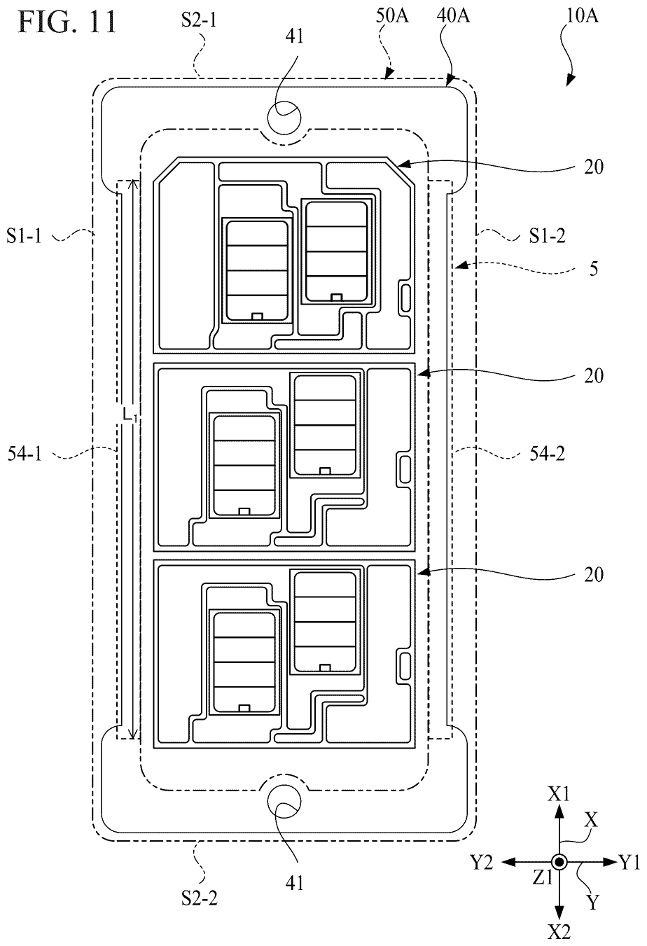

FIG. 11 is an explanatory diagram showing a semiconductor module 10A according to the Second Embodiment. The semiconductor module 10A has substantially the same configuration as the semiconductor module 10 according to the First Embodiment, except that a base 40A is included in place of the base 40 and a housing 50A is included in place of the housing 50. It should be noted that in FIG. 11, the housing 50A is shown in long-dash, double short-dash line, for clarity of contrast between the base 40A and the housing 50A.

The housing 50A has substantially the same configuration as the housing 50 according to the First Embodiment, except that the number of holes 53 is different, the arrangement of the holes 53 is different, and the second adhering portions 55 are omitted. The housing 50A includes two holes 53 that are provided at locations corresponding to the respective middles of the second sides S2 (or at locations close to each of the middles of the second sides S2). The housing 50A includes the first adhering portions 54 shown in dashed line shown in FIG. 11 as in the First Embodiment. However, the housing 50A includes no second adhering portions 55. It should be noted that the number of holes 53 is different and the arrangement of the holes 53 is different, and the second adhering portions 55 are omitted and other elements of the housing 50A differ from those of the housing 50 as appropriate.

On the other hand, the base 40A has substantially the same configuration as the base 40 according to the First Embodiment, except that the number of holes 41 is different and the arrangement of the holes 41 is different. The base 40A includes two holes 41 that are provided at locations corresponding to the respective two holes 53 (or at locations close to each of the two holes 53).

According to the Second Embodiment described above, it is possible to reduce damage to the housing 50A due to screwing. As described above, the two holes 53 are provided at the locations corresponding to the respective middles of the second sides S2. Thus, damage due to screwing is unlikely to occur at a portion of the housing 50A that is along the second side S2. Consequently, in a state in which the second adhering portions 55 are omitted, it is possible to reduce damage to the housing 50A due to screwing.

### 3. Modifications

This disclosure is not limited to each of the embodiments described above, and various modifications described below can be made thereto. In addition, each of the embodiments and each of the modifications may be combined with others as appropriate.

### 3-1. First Modification

In each of the embodiments described above, a configuration is described in which the length of the first side S1 is greater than the length of the second side S2. However, this disclosure is not limited to this configuration, and the length of the first side S1 may be less than the length of the second side S2.

### 3-2. Second Modification

In each of the embodiments described above, a configuration may be described in which the external terminal 60 is integrally formed by insert molding together with the housing 50 or together with the housing 50A. However, this disclosure is not limited to this configuration, and the external terminal 60 may be inserted either into a terminal hole of the housing 50 or into a terminal hole of the housing 50A after the housing 50 or the housing 50A is formed.

### 3-3. Third Modification

In each of the embodiments described above, a configuration is described in which the external terminal 60 includes the pin 61 and the leg 62. However, this disclosure is not limited to this configuration, and the shape of the external terminal 60 may be freely selected. In addition, each of the semiconductor modules 10 and 10A may not include an external terminal 60 for control.

### 4. Supplemental Notes

The following configurations are derivable from the foregoing embodiments and modifications.

A semiconductor module according to one aspect (first aspect) of this disclosure includes a plate-shaped base made of metal, and a frame-shaped housing made of a resin composition, the housing having an adhering portion adhering to an outer peripheral portion of the base, wherein in plan view, an outer periphery of the housing includes a pair of first sides facing each other, and a pair of second sides facing each other, wherein a portion of the housing corresponding to each of the second sides is provided with at least one hole for screwing a heat dissipating member, wherein the adhering portion includes a plate-shaped first adhering portion extending along each of the first sides, wherein in plan view, the first adhering portion overlaps an outer periphery of the base, and wherein inequality T₁<0.42×L₁² is satisfied, when T₁ is T₁ meters that denote a thickness of the first adhering portion, and L₁ is L₁ meters that denote a length of the first adhering portion.

According to this aspect, in plan view, the first adhering portion overlaps the outer periphery of the base. Thus, by deformation of the first adhering portion, it is possible to reduce stress, which occurs in the housing when the housing is screwed to the heat dissipating member. In particular, the thickness T₁ and the length L₁ of the first adhering portion satisfy inequality T₁<0.42×L₁². Thus, by deformation of the first adhering portion, it is possible to appropriately reduce stress that occurs in a portion of the housing that is along the first side.

In an example (second aspect) of the first aspect, inequality W₁>T₁ is satisfied, when W₁ is a width of the first adhering portion. According to this aspect, by deformation of the first adhering portion, it is possible to appropriately reduce stress that occurs in a portion of the housing that is along the first side.

In an example (third aspect) of the first or second aspect, a length of each of the first sides is greater than a length of each of the second sides. According to this aspect, compared to a configuration in which the length of each of the first sides is less than the length of each of the second sides, it is possible to firmly fix the housing to the heat dissipating member by screwing the housing to the heat dissipating member if the number of holes is small.

In an example (fourth aspect) of any of the first to third aspects, the at least one hole comprises two holes provided to the portion of the housing corresponding to each of the second sides. According to this aspect, it is possible to firmly fix the housing to the heat dissipating member by screwing the housing to the heat dissipating member.

In an example (fifth aspect) of any of the first to fourth aspects, the adhering portion includes a plate-shaped second adhering portion extending along each of the second sides, in plan view, the second adhering portion overlaps the outer periphery of the base, and inequality T₂<0.42×L₂² is satisfied, when T₂ is T₂ meters that denote a thickness of the second adhering portion, and L₂ is L₂ meters that denote a length of the second adhering portion. According to this aspect, by deformation of the second adhering portion, it is possible to reduce stress that occurs in a portion of the housing that is along the second side.

In an example (sixth aspect) of the fifth aspect, inequality W₂>T₂ is satisfied, when W₂ is a width of the second adhering portion. According to this aspect, by deformation of the second adhering portion, it is possible to appropriately reduce stress that occurs in a portion of the housing that is along the second side.

In an example (seventh aspect) of any of the first to sixth aspects, the semiconductor module further comprises an insulating substrate joined to the base. According to this aspect, a warp is likely to occur in the base due to stress caused by joining the insulating substrate to the base. Thus, in this aspect, an advantage is significantly obtained in that by deformation of the adhering portion, it is possible to reduce stress, which occurs in the housing when the housing is screwed to the heat dissipating member.

### DESCRIPTION OF REFERENCE SIGNS

5 . . . adhering portion, 10 . . . semiconductor module, 10A . . . semiconductor module, 10X . . . semiconductor module, 20 . . . insulating substrate, 21 . . . insulating board, 22 . . . conductive board, 23 . . . conductive pattern, 30 . . . semiconductor chip, 40 . . . base, 40A . . . base, 41 . . . hole, 50 . . . housing, 50A . . . housing, 50X . . . housing, 51 . . . terminal hole, 52 . . . hole, 53 . . . hole, 54 . . . first adhering portion, 54-1 . . . first adhering portion, 54-2 . . . first adhering portion, 55 . . . second adhering portion, 55-1 . . . second adhering portion, 55-2 . . . second adhering portion, 60 . . . external terminal, 61 . . . pin, 62 . . . leg, 70 . . . wire, 80 . . . lid, 100 . . . heat dissipating member, 101 . . . mounting surface, 200 . . . screw, B1 . . . joining material, B2 . . . adhesive, S1 . . . first side, S1-1 . . . first side, S1-2 . . . first side, S2 . . . second side, S2-1 . . . second side, S2-2 . . . second side, T₁ . . . thickness, T₂ . . . thickness, W₁ . . . width, W₂ . . . width.

What is claimed is:

1. A semiconductor module comprising:
a plate-shaped base made of metal; and
a frame-shaped housing made of a resin composition, the housing having an adhering portion adhering to an outer peripheral portion of the base,
wherein in plan view, an outer periphery of the housing includes a pair of first sides facing each other and a pair of second sides facing each other,
wherein a portion of the housing corresponding to each of the second sides is provided with at least one hole for screwing a heat dissipating member,
wherein the adhering portion includes a plate-shaped first adhering portion extending along each of the first sides,
wherein in plan view, the first adhering portion overlaps an outer periphery of the base, and
wherein inequality T₁<0.42×L₁² is satisfied, when T₁ is T₁ meters that denote a thickness of the first adhering portion, and L₁ is L₁ meters that denote a length of the first adhering portion.

2. The semiconductor module according to claim 1, wherein inequality W₁>T₁ is satisfied, when W₁ is a width of the first adhering portion.

3. The semiconductor module according to claim 1, wherein a length of each of the first sides is greater than a length of each of the second sides.

4. The semiconductor module according to claim 3, wherein the at least one hole comprises two holes provided to the portion of the housing corresponding to each of the second sides.

5. The semiconductor module according to claim 4,
wherein the adhering portion includes a plate-shaped second adhering portion extending along each of the second sides,
wherein in plan view, the second adhering portion overlaps the outer periphery of the base, and
wherein inequality T₂<0.42×L₂² is satisfied, when T₂ is T₂ meters that denote a thickness of the second adhering portion, and L₂ is L₂ meters that denote a length of the second adhering portion.

6. The semiconductor module according to claim 5, wherein inequality W₂>T₂ is satisfied, when W₂ is a width of the second adhering portion.

7. The semiconductor module according to claim 1, further comprising an insulating substrate joined to the base.
